(19) United States
(12) Patent Application Publication
(10) Pub. No.: US 2007/0296056 A1
(43) Pub. Date: Dec. 27, 2007

(54) Integrated Circuits Having Controlled Inductances

(75) Inventors: Anthony L. Coyle, Plano, TX (US); Reynaldo C. Javier, Richardson, TX (US); Jeffrey G. Holloway, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/426,591

(22) Filed: Jun. 27, 2006

(51) Int. Cl. H01L 29/00

(52) U.S. Cl. 257/531

(57) ABSTRACT

An electronic device has a semiconductor chip (101) with a surface and an electric circuit including terminals on the surface. The circuit has a first (103) and a second terminal (104) with a metallurgical composition for wire bonding. The chip has a conductive wire (120) above the chip surface, which has a length and a first and a second end; the first end is attached to the first terminal and the second end to the second terminal. The wire is shaped to form at least one sequence of a concave and a convex portion. The sequence may be configured to form a loop, or multiple wire loops resulting in a spiraling wire coil. The number, shape, and spatial sequence of the loops control the electrical inductance of the wire; the inductance is selected to fine-tune the high frequency characteristics of the circuit.

### FIELD OF THE INVENTION

The present invention is related in general to the field of semiconductor devices and processes, and more specifically to structure and method of controlled inductances for integrated circuits.

### DESCRIPTION OF THE RELATED ART

Time to Market is a significant factor for the success of semiconductor components in the rapidly expanding markets served by electronic products. All too often, though, a redesign of the semiconductor component is required in order to satisfy the changing characteristic requested by a customer or by the technical needs of a new trend in products.

Another significant success factor for semiconductor products is the capability to satisfy the market trend for miniaturization. This trend is driven and accelerated by new applications for semiconductor products such as hand-held appliances, which prefer small-size components. However, an unwelcome roadblock to miniaturization appears, whenever a component has to be added as a discrete external part to the product, rather than to be integrated into already existing devices.

In the course of miniaturization, it is further becoming tougher to narrow the process windows in semiconductor manufacturing, since these windows are most often determined by the inherent statistical variations of the processes used. The industry is, therefore, always looking for any additional help to fine-tune the characteristics of finished semiconductor circuits as a means to indirectly widen the process windows.

### SUMMARY OF THE INVENTION

Applicants recognize the need for fine-tuning the high frequency characteristics of rf-circuits by means which are internal to the product rather than by adding external components. The methodology should be coherent, low-cost, and flexible enough to be applied to different semiconductor product families and a wide spectrum of design and process variations. With the capability of adjusting circuits internally, the product miniaturization can be supported and time to market can be reduced.

One embodiment of the invention is an electronic device, which has a semiconductor chip with a surface and an electric circuit including terminals on the surface. The circuit has a first and a second terminal with a metallurgical composition for wire bonding. The chip has a conductive wire above the chip surface, which has a length and a first and a second end; the first end is attached to the first terminal and the second end to the second terminal. The wire is shaped to form at least one sequence of a concave and a convex portion.

The sequence of concave and convex wire portions may be configured to form a loop, or multiple wire loops resulting in a spiraling wire coil. In many devices the coil may be shaped about linearly along the line representing the shortest distance between the first and the second terminals. The number, shape, and spatial sequence of the loops control the electrical inductance of the wire. The inductance, in turn, is selected to fine-tune the high frequency characteristics of the circuit.

Another embodiment of the invention is a method for fabricating an inductance control for an electronic device. A chip is provided, which has a surface and an electric circuit including terminals on the surface. A first and a second terminal are formed with a metallurgical composition suitable for wire bonding. A conductive wire, such as a gold or copper wire, is then provided, which has a length and a first and a second end. The first wire end is attached to the first terminal. Then, the wire is shaped to form at least one sequence of a concave and a convex portion; alternatively, the sequence is configured to form a loop. Finally, the second wire end is attached to the second terminal.

The number, shape and spatial sequence of the concave and convex wire portions are selected to control the electrical inductance of the wire. The sequence of concave and convex wire portions may be configured to form a loop; multiple loops may form a spiraling wire coil. The method may further include the step of positioning the individual loops approximately normal to the chip surface.

Inductances from 1 to 3 nH up to 20 nH or more can be created. The wire and coils may be included in an encapsulation of the circuit and thus be internal to the semiconductor product.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a schematic side view of a wire coil attached to device terminals on the surface of the device, according to an embodiment of the invention.

FIG. 2 is a schematic perspective view of the progression of the wire dispensed to create the wire loops of a coil.

FIG. 3 is a schematic top view of a sequence of concave and convex portions of a wire inductor attached to terminals on the surface of a device, according to another embodiment of the invention.

FIG. 4 is a schematic top view of the progression of the wire dispensed to create the sequence of concave and convex portions to create the meandering windings of the inductor.

### DETAILED DESCRIPTION OF THE PREFERRED EMBODIMENTS

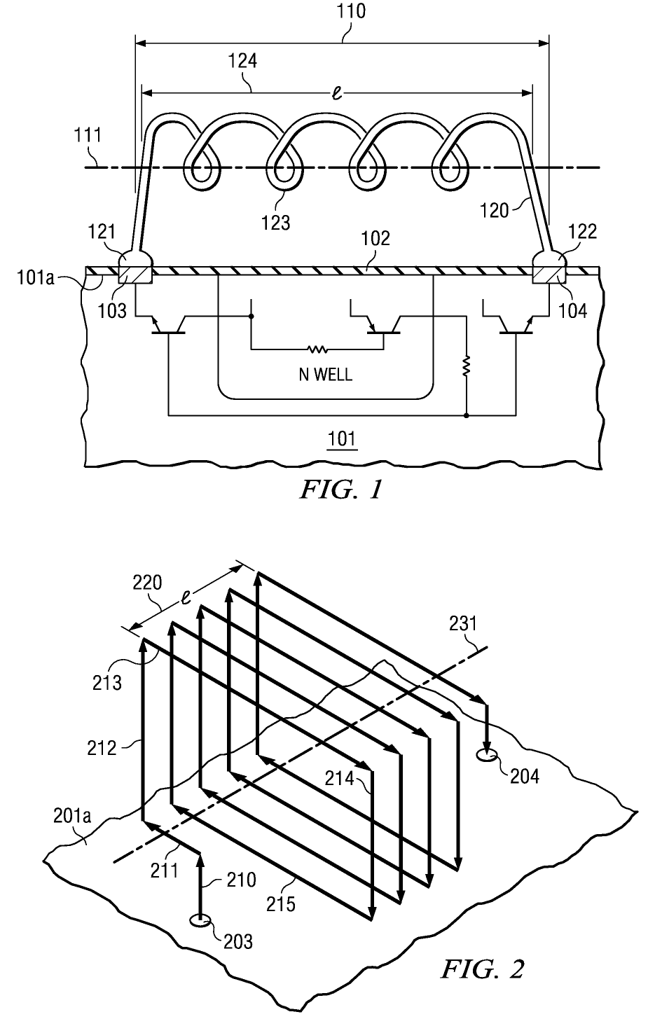

In FIG. 1, a portion of a semiconductor chip 101 is represented, which includes some high-frequency circuitry. The chip cross section shows the chip surface 101a; as illustrated in FIG. 1, surface 101a preferably has an overcoat 102, which not only protects the underlying semiconductor material and circuitry against ambient disturbances such as moisture, but also is electrically insulating. Preferably, the overcoat includes a layer of silicon nitride, or oxynitride, or a stack of a layer of silicon dioxide and an outermost layer of silicon nitride.

The surface includes bond pads of the integrated circuit (not shown in FIG. 1), which are used for attaching the electrical input-output connections to the circuit using wire bond or solder connections. The surface further includes first terminal 103 and second terminal 104, which serve to fine-tune the rf-characteristics of the circuit. Terminals 103 and 104 are configured as ports of an electric current through the circuit and have a metallurgical surface composition suitable for wire bonding, especially gold wire bonding. Preferably, the terminal surface includes a thin layer of aluminum or a thin layer of nickel with a top layer of gold. Second terminal 104 is spaced by distance 110 in a direction from first terminal 103. Distance 110 is for many devices in the range from about 2 to 6 mm. The direction is indicated in FIG. 1 by dashed line 111.

The side view of FIG. 1 shows a conductive wire 120 for connection between first terminal 103 and second terminal 104. Wire 120 has a first end 121, a second end 122, and a length. Wire 120 is preferably a bonding wire made of gold or a gold alloy, with a diameter ranging from about 15 to 120 μm, preferably 25 μm. The gold alloy may have a small percentage admixture of copper or other metals for hardening. Alternatively, wire 120 may be copper or a copper alloy with a preferred diameter of 15 to 30 μm.

As FIG. 1 shows, first end 121 of wire 120 is attached to first terminal 103; the second wire end 122 is attached to terminal 104. The wire attachment to the pads may be by ball bonding, stitch bonding, or both. It is preferred that the attachments are performed so that wire 120 stays above surface 101.

The wire is shaped to form at least one sequence of a concave and a convex portion. Specifically, the sequence of concave and convex wire portions may be configured to form a loop 123. The loop has a diameter and a cross section of area F. In FIG. 1, multiple wire loops result in a spiraling wire coil of length l (designated 124). When the coil is shaped about linearly, as depicted in FIG. 1, it may be oriented along the line representing the shortest distance 110 between first terminal 103 and second terminal 104. When the coil has an approximately linear shape, it may be attributed an axis 111. Furthermore, the wire loops may be positioned approximately normal to the chip surface in order to easily control the added inductance.

The self induction coefficient L, or simply the induction L, of an elongated coil, which has n tight windings or loops so that the magnetic field outside the coil can be neglected, is proportional to n². The proportionality factor includes the magnetic permeability u (which has the dimension joule·sec²/coulomb²·meter and is equal to 1 for vacuum, and close to 1 for air) multiplied by the cross section F (meter²) of the coil, divided by the length l (meter) of the coil.

L=(μF/l)n².

The unit of inductance is 1 Henry (H)=1 joule·sec²/coulomb²=1 volt·sec/ampere. The inductance in integrated circuits is small and thus practically expressed in 10⁻⁹H=nH.

The schematic perspective view of FIG. 2 illustrates in more detail, how the wire can be dispensed to create a series of loops in order to form a coil. A bonder with a wire-loaded capillary can be instructed to have the capillary perform the movements and bonding actions required to create the loops and attachments of the coil. Starting at attachment terminal 203 on surface 201a, the wire is attached to terminal 203 and then pulled upward, away from the surface, for the length 210; then, after changing the movement direction of the capillary approximately 90°, the wire is pulled sideways for the length 211 in a certain direction. After another capillary movement bend of about 90°, the wire is dispensed upwards again for the length 212, then, after another bend of about 90°, sideways for the length 213 greater than length 211, yet in the direction opposite to direction of length 211. Turning the capillary movement approximately 90°, the wire is moved downward, towards the surface, for the length 214 about equal to length 212. Finally, the wire is turned about 90° in the same direction as length 211, for a length 215 greater than length 211. In order for the wire to complete the first loop without touching a previous wire length, this loop and any following loops are somewhat stretched in the direction towards the final terminal 204.

When desirable, the cycle can be repeated. A bonder with a wire-loaded capillary can be taught to perform this wire movements in a repetitive manner. After the first loop, the capillary creates more loops of about the same diameter, cross sectional area, and orientation. Preferably, the capillary dispenses the wire evenly and advances evenly from loop to loop. The resulting coil thus stretches evenly along the length l (designated 220) and exhibits an axis 231. The orientation of the loop areas is preferably about normal to the direction of the axis. The wire is finally attached to terminal 204 located on surface 201a.

As an example, a wire of 25 μm diameter arranged in 4 to 5 loops of 150 μm diameter for a total coil length of 4 to 5 mm can produce an inductance of about 30 to 40 nH. A single wire loop between pads 203 and 204 can produce about 2 to 3 nH.

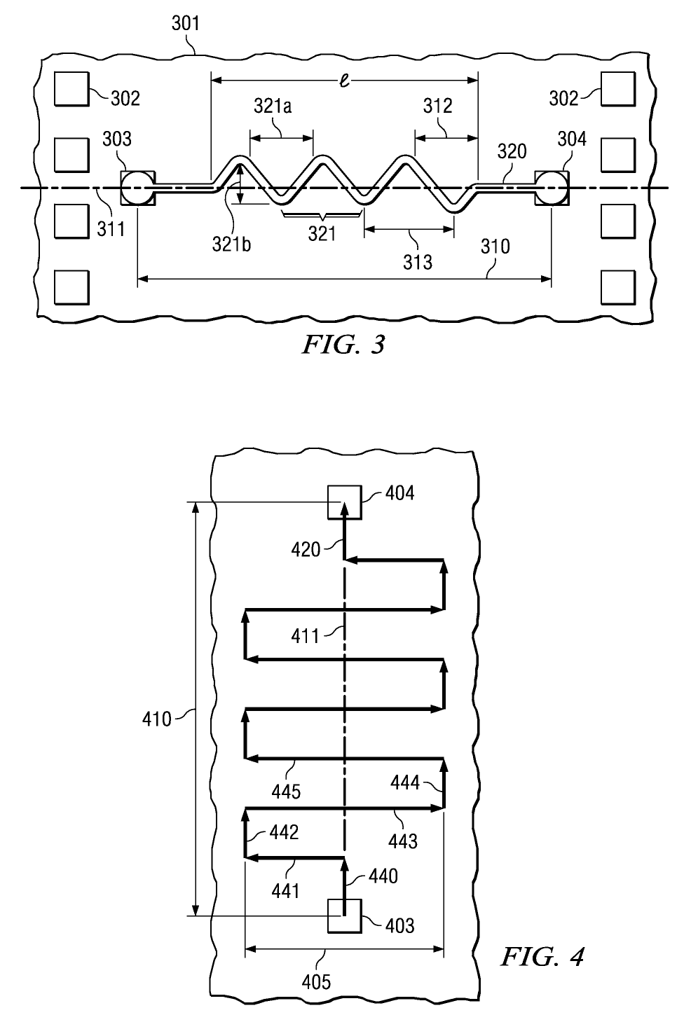

Another embodiment of the invention is a meandering wire configuration on the chip surface, or slightly above the chip surface, to add a specific inductance to the circuit and thus modify the circuit inductance. The length of the wire includes a sequence of concave and convex portions, wherein the number, shape, and spatial sequence of the portions control the electrical inductance of the wire. The top view of FIG. 3 depicts a portion of a semiconductor chip. The chip surface 301 preferably has an insulating overcoat such as silicon nitride or silicon oxynitride. The surface includes a number of bond pads 302 of the integrated circuit (inside the semiconductor, not shown in FIG. 3), which are used for attaching the electrical input/output connections to the circuit; in some devices, pads 102 have a metallurgical surface configuration amenable for wire bonding, in other devices, pads 102 have a metallurgical configuration amenable for solder attachment.

The surface in FIG. 3 further includes first terminal 303 and second terminal 304, which serve to attach the looped wire formed to add inductance to the circuit and thus fine-tune the rf-characteristics of the circuit. Terminals 303 and 304 are configured as terminals of an electric current through the circuit and have a metallurgical surface composition suitable for wire bonding, especially gold wire bonding. Preferably, the terminal surface includes a thin layer of aluminum or a thin layer of nickel with a top layer of gold. Second terminal 304 is spaced by distance 310 in a direction from first terminal 303. Distance 310 is for many devices in the range from about 2 to 6 mm. The direction is indicated in FIG. 3 by dashed line 311.

FIG. 3 shows a wire 320 for connection between first terminal 303 and second terminal 304. Wire 320 is preferably a bonding wire made of gold or a gold alloy, with a diameter ranging from about 15 to 120 μm, preferably 25 μm. The gold alloy may have a small percentage admixture of copper or other metals for hardening. Alternatively, wire 320 may be copper or a copper alloy with a preferred diameter of 15 to 30 μm.

As FIG. 3 shows, the first end of wire 320 is attached to terminal 303. The wire has then alternating concave portions, such as 312, and convex portions, such as 313, to result in alternating windings 321. The windings are generally in an orientation transecting the direction 311 of the terminal spacing 310. The second end of wire 320 is attached to the second terminal 304. The wire attachment to the pads may be by ball bonding, stitch bonding, or both. As stated, it is preferred that the attachments are performed so that wire 320 stays clear of surface 301 for the most part of length 310; alternatively, when the thinness of devices is at a premium, the wire windings of the inductor may lay on the insulating layer of the chip surface.

The sum of the loops 321 extend over the length l in FIG. 3 and represents a zig-zag inductor of wire 320. Each zig-zag 321 spans a length 321a and has an amplitude 321b.

The schematic top view of FIG. 4 represents an example, how the sequence of alternating concave and convex wire portions, resulting in a meandering zig-zag inductor, is actually shaped during the process of forming the controlled inductor from wire 420. It is preferred to use a bonder with a wire-loaded capillary; the bonder capillary is instructed to dispense the wire in substantially linear stretches connected by turns of an angle of approximately 90°.

The lengths of the wire stretches and the angled turns construct a sequence of meandering windings, wherein the dominating length is designated 405. The sequence of the windings approximate a “coil” composed of windings meandering along an axis 411. The total length of the “coil” is 410. The first end of wire 420 is attached to terminal 403, the second end to terminal 404.

As an example, a wire of 25 μm diameter arranged in 3 to 4 windings of 150 μm length for a total meander length of 4 to 5 mm can produce an inductance of about 20 nH.

When the bonder capillary has the wire attached to terminal 403 and begins forming the meandering inductor in FIG. 4, it is preferred that it pulls the wire in the direction toward pad 404 as well as slightly upward from the chip surface for the length 440. After a bend of about 90°, the capillary moves the wire sideways for the length 441 in a direction about normal to the direction toward pad 404. Then, after a bend of about 90°, the wire is dispensed again in the direction towards pad 404 for the length 442. Then, after another bend of about 90°, sideways in the direction opposite to direction of length 441, for the length 443 greater than length 441. Then turning about 90°, the capillary moves in the direction towards pad 404 for the length 444; this length is about equal to length 442. After another turn of 90°, the wire forms length 445 in the same direction as length 441; length 445 is about equal to length 443. The first sequence of a concave portion and a convex portion, resulting in a meander winding, is completed.

When desirable, the cycle can be repeated. The capillary creates a number of windings of about the same amplitude, spatial excursion, and orientation. The resulting meandering inductor stretches along length l and has an “axis” 411. The orientation of the meander windings are approximately normal to the direction of the axis. The wire is finally attached to terminal 404.

As described in FIGS. 2 and 4, an embodiment of the invention is a method for fabricating an inductance control for an electronic device. The method can be applied to any semiconductor chip with a surface and an electric component; the component is usually a high frequency circuit with input/output ports on the surface, but it may alternatively be a discrete component.

On the chip surface, a first terminal is formed, which is metallurgically amenable to wire bonding, preferably gold wire bonding. Preferred terminal surfaces include aluminum or a layer stack of nickel and gold. A second terminal is spaced in a direction from the first terminal.

A conductive wire for connection between the terminals is then provided; the wire has a length, a fist end and a second end. Preferred wire choices include gold or copper.

The bonding of the wire to the terminals progresses by the steps of:

attaching the first wire end to the first terminal; the connection may be a ball bond, a stitch bond, or both;

then shaping the wire length so that the wire forms at least one sequence of a concave and a convex portion; it is preferred that these portions follow each other to form a loop;

winding the wire to create one or more loops to form a coil; preferably, the loops have approximately the same size and orientation; preferably they advance evenly. The coil is preferably a linear coil with an axis; the axis is preferably oriented in the direction of the terminal spacing. The loops are preferably oriented normal to the coil axis;

attaching the second end of the wire to the second terminal.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

We claim:

1. An electronic device comprising:
a semiconductor chip having a surface and an electric circuit including terminals on the surface;
a first and a second terminal having a metallurgical composition for wire bonding;
a conductive wire above the chip surface, the wire having a length and a first and a second end, the first end attached to the first terminal and the second end attached to the second terminal; and
the wire shaped to form at least one sequence of a concave and a convex portion.

2. The device according to claim 1 wherein the number, shape and spatial sequence of the concave and convex wire portions control the electrical inductance of the wire.

3. The device according to claim 1 wherein the sequence of concave and convex wire portions is configured to form a loop.

4. The device according to claim 3 wherein multiple wire loops form a spiraling wire coil.

5. The device according to claim 4 wherein the wire coil is shaped approximately linearly along the line representing the shortest distance between the first and the second terminals.

6. The device according to claim 3 wherein an individual wire loop can be approximated by a plane and the plane is oriented substantially normal to the chip surface.

7. A method for fabricating an inductance control for an electronic device, comprising the steps of:
providing a semiconductor chip having a surface and an electric circuit including terminals on the surface;
forming a first and a second terminal having a metallurgical composition for wire bonding;
providing a conductive wire having a length and a first and a second end;
attaching the first wire end to the first terminal;
then shaping the wire so that the wire forms at least one sequence of a concave and a convex portion; and
then attaching the second wire end to the second terminal.

8. The method according to claim 7 wherein the number, shape and spatial sequence of the concave and convex wire portions are selected to control the electrical inductance of the wire.

9. The method according to claim 7 wherein the connection to the first terminal is a ball bond and the connection to the second terminal is a stitch bond.

10. The method according to claim 7 wherein the wire includes gold.

11. The method according to claim 7 wherein the wire includes copper.

12. The method according to claim 7 wherein the sequence of concave and convex wire portions is configured to form a loop.

13. The method according to claim 12 wherein multiple loops form a spiraling wire coil.

14. The method according to claim 13 further including the step of positioning the individual loops approximately normal to the chip surface.
